(19) United States
(12) Patent Application Publication
(10) Pub. No.: US 2017/0264079 A1
(43) Pub. Date: Sep. 14, 2017

(54) SELF-LOCKED DIODE LASER INTEGRATED WITH MICRO-DISK RESONATOR

(71) Applicant: ELECTRONICS AND TELECOMMUNICATIONS RESEARCH INSTITUTE, Daejeon (KR)

(72) Inventor: Kwang Ryong OH, Daejeon (KR)

(73) Assignee: ELECTRONICS AND TELECOMMUNICATIONS RESEARCH INSTITUTE, Daejeon (KR)

(21) Appl. No.: 15/271,399

(22) Filed: Sep. 21, 2016

(30) Foreign Application Priority Data
Mar. 11, 2016 (KR) 10-2016-0029518

(51) Int. Cl. H01S 5/065; H01S 5/323

(52) U.S. Cl. CPC H01S 5/0657; H01S 5/323

(57) ABSTRACT

Disclosed is a self-locked laser system, including: a semiconductor substrate; a laser diode including a first semiconductor part disposed on the semiconductor substrate, and which generates an optical signal; an unidirectional Whispery Gallery Mode (WGM) resonator including a second semiconductor part disposed on the semiconductor substrate; and a structure emitting an optical signal self-locked by the optical signal of the laser diode, in which the laser diode and the resonator are optically coupled on the semiconductor substrate.

### CROSS-REFERENCE TO RELATED APPLICATION

The present application claims priority to Korean patent application number 10-2016-0029518 filed on Mar. 11, 2016, the entire disclosure of which is incorporated herein in its entirety by reference.

### BACKGROUND

1. Field

The present disclosure relates to a self-locked diode laser.

2. Description of the Related Art

A laser with a high-purity spectrum having a very small line width is a core element which determines the highest sensitivity characteristic in optical frequency metrology. Many various applications, such as an atomic clock, high-resolution spectroscopy, quantum information optics, high-resolution optical sensing, and Light Detection and Ranging (LIDAR), require a laser having a fine line width for the optimization of performance thereof. In addition, for a high-rate data optical communication system including coherent communication, a laser with a low frequency and amplitude noise is required.

In this case, a laser system having a fine line width is being developed.

### SUMMARY

The present disclosure has been made in an effort to solve the above-described problems associated with the prior art, and provides a self-locked diode laser, which includes a semiconductor laser diode and an external resonator on a single substrate, thereby being easily implemented and/or manufactured, and being capable of securing an optical signal having a fine line width.

An exemplary embodiment of the present disclosure provides a self-locked laser system, including: a semiconductor substrate; a laser diode including a first semiconductor part disposed on the semiconductor substrate, and which generates an optical signal; an unidirectional Whispery Gallery Mode (WGM) resonator including a second semiconductor part disposed on the semiconductor substrate; and a structure which emits an optical self-locked signal by the optical signal of the laser diode, in which the laser diode and the resonator are optically coupled on the semiconductor substrate.

The laser diode may include an incident surface inclined at a predetermined angle.

The first semiconductor part may include an n-type doped first lower clad layer, a p-type doped first upper clad layer, and a first active layer disposed between the first lower clad layer and the first upper clad layer.

The second semiconductor part may include an n-type doped second lower clad layer, a p-type doped second upper clad layer, and a second active layer disposed between the second lower clad layer and the second upper clad layer.

The first active layer and the second active layer may include a III-V compound semiconductor layer.

The laser diode may include any one selected from a Fabry-Perot (FP) laser diode, a Distributed Feed-Back (DFB) laser diode, and a Distributed Bragg Reflector (DBR) laser diode.

The self-locked diode laser system may further include a lens disposed between the laser diode and the unidirectional WGM resonator and which collects the optical signal generated by the laser diode.

The self-locked diode laser system may further include a lens which collects the optical signal generated by the laser diode between the laser diode and the unidirectional WGM resonator, in which the laser diode and the unidirectional WGM resonator are disposed on separate substrates, respectively.

The unidirectional WGM resonator may include a passive wave guide having any one selected from low-loss materials including silicon, silica, or CaF₂.

The unidirectional WGM resonator may be hybrid-integrated with the laser diode on the semiconductor substrate.

According to the exemplary embodiment of the present disclosure, it is possible to provide the laser system, which may be easily implemented and manufactured, and outputs an optical signal having an ultra-fine line width by providing a laser diode and a resonant structure optically coupled with the laser diode on a single semiconductor substrate.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic top plan view of a laser system according to an exemplary embodiment of the present disclosure.

FIG. 2 is a cross-sectional view taken along line I-I′ and II-II″ of FIG. 1.

FIGS. 3 to 14 are cross-sectional views sequentially illustrating a method of manufacturing the laser system according to an exemplary embodiment of the present disclosure.

### DETAILED DESCRIPTION OF THE INVENTION

The present disclosure may be variously modified and have various forms, so that specific exemplary embodiments will be illustrated in the drawings and described in detail in the text. However it should be understood that the invention is not limited to the specific embodiments, but includes all changes, equivalents, or alternatives which are included in the spirit and technical scope of the present disclosure.

In the description of respective drawings, similar reference numerals designate similar elements. In the accompanying drawings, sizes of structures are illustrated to be enlarged compared to actual sizes for clarity of the present disclosure. Terms “first”, “second”, and the like may be used for describing various constituent elements, but the constituent elements should not be limited to the terms. For example, a first element could be termed a second element, and similarly, a second element could be also termed a first element without departing from the scope of the present disclosure. As used herein, the singular forms are intended to include the plural forms as well, unless the context clearly indicates otherwise.

In the present disclosure, it should be understood that terms “include” or “have” indicates that a feature, a number, a step, an operation, a component, a part or the combination those of described in the specification is present, but do not exclude a possibility of presence or addition of one or more other features, numbers, steps, operations, components, parts or combinations, in advance. It will be understood that when an element such as a layer, film, region, or substrate is referred to as being “on” another element, it can be directly on the other element or intervening elements may also be present. On the contrary, it will be understood that when an element such as a layer, film, region, or substrate is referred to as being “beneath” another element, it can be directly beneath the other element or intervening elements may also be present.

As used in the present specification, a term “optical signal” may refer to emitted optical energy having a wavelength which is implementable in a semiconductor laser. The defined optical signal may include ultraviolet rays, visible rays, and infrared rays, but is not limited thereto.

Hereinafter, an exemplary embodiment of the present disclosure will be described in detail with reference to the accompanying drawings.

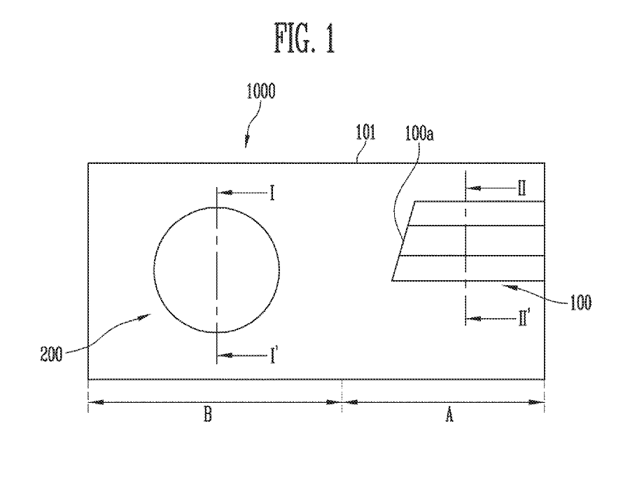

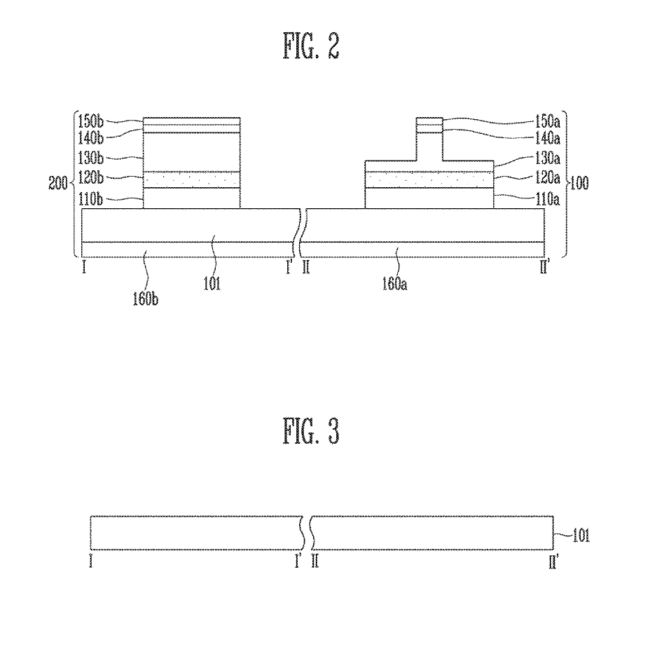

FIG. 1 is a schematic top plan view of a laser system according to an exemplary embodiment of the present disclosure, and FIG. 2 is a cross-sectional view taken along line I-I′ and II-II″ of FIG. 1.

Referring to FIGS. 1 and 2, a laser system 1000 according to an exemplary embodiment of the present disclosure may include a laser diode 100 and a resonator 200 disposed on a semiconductor substrate 101.

The semiconductor substrate 101 may be divided into a first region A and a second region B. The laser diode 100 may be disposed in the first region A of the semiconductor substrate 101, and the resonator 200 may be disposed in the second region B of the semiconductor substrate 101.

The division of the semiconductor substrate 101 into the first region A and the second region B is for the convenience of description, and the present disclosure is not limited thereto. Here, the laser diode 100 and the resonator 200 may be disposed on the semiconductor substrate 101 and optically coupled with each other.

The laser diode 100 outputs an optical signal having a specific wavelength. Here, the laser diode 100 may include any one selected from a Fabry-Perot (FP) laser diode, a Distributed Feed-Back (DFB) laser diode, and a Distributed Bragg Reflector (DBR) laser diode.

The resonator 200 is a Whispery Gallery Mode (WGM), and may have a radiation angle in a single direction and may be optically coupled with the laser diode 100.

The laser diode 100 outputs an optical signal having a specific wavelength. The optical signal may be modulated into a self-locked optical signal having a fine line width through the optical coupling of the laser diode 100 and the resonator 200.

An incident surface 100a of the laser diode 100 is inclined at a predetermined angle in order to remove a resonant phenomenon between the incident surface 100a and the resonator 200.

The laser diode 100 may include a first semiconductor part disposed on the semiconductor substrate 101. The first semiconductor part may include a first lower clad layer 110a, a first active layer 120a, and a first upper clad layer 130a.

The semiconductor substrate 101 may be a III-V semiconductor substrate. For example, the semiconductor substrate 101 may be an n-type gallium arsenide (GaAs) substrate, or an n-type indium phosphide (InP) substrate.

In the exemplary embodiment of the present disclosure, the first lower clad layer 110a may include an n-type doped indium phosphide (InP), and the first upper clad layer 130a may include a p-type doped indium phosphide (InP). The first lower clad layer 110a and the first upper clad layer 130a may be used for substantially limiting/restricting light within the laser diode 100.

The first active layer 120a may be disposed between the first lower clad layer 110a and the first upper clad layer 130a. The first active layer 120a may include an indium-phosphorous-based semiconductor layer, for example, indium-gallium-arsenic-phosphorous (InGaAsP) based quantum wells. Here, the quantum well may include a structure having a thin layer of a narrow bandgap semiconductor fitted between thick layers of a wide bandgap material.

The quantum well may include a germanium thin layer fitted between silicon, and may include other materials. Additionally, the aforementioned various layers may be formed by alternative doping and with geometrical structures.

As described above, the first semiconductor part having the first lower clad layer 110a, the first active layer 120a, and the first upper clad layer 130a may serve as a wave guide layer.

The laser diode 100 may further include a first upper electrode 150a and a first lower electrode 160a which face each other with the first semiconductor part interposed therebetween.

The first lower electrode 160a may be disposed on a lower surface of the semiconductor substrate 101, and the first upper electrode 150a may be disposed on the first upper clad layer 130a with a first ohmic layer 140a interposed therebetween. The first lower electrode 160a may include an n-type electrode, and the first upper electrode 150a may include a p-type electrode. The first ohmic layer 140a may include a p-type indium-gallium-arsenide (InGaAs) layer.

The resonator 200 may be disposed in the first region A of the semiconductor substrate 101 when viewed on a plane. It is illustrated that the resonator 200 and the laser diode 100 are spaced apart from each other on the semiconductor substrate 101 by a predetermined interval, but this is for the convenience of description, and the present disclosure is not limited thereto. For example, the resonator 200 and the laser diode 100 may be integrally formed on the semiconductor substrate 101.

The resonator 200 may include a micro disc resonator. For example, the micro disc resonator may be an unidirectional Whispery Gallery Mode (WGM) resonator having a radiation angle in a single direction.

As illustrated in the drawing, the resonator 200 may be formed in a circular shape, but is not limited thereto, and may be formed in various forms. The resonator 200 itself may be formed of one set of wave guides, and at least one of the wave guides may be a closed loop coupled to an input and an output, for example, the waveguide, of a specific light source.

Further, the resonator 200 may include a passive wave guide including any one of low loss materials having silicon, silica, or CaF₂. The resonator including the passive wave guide may be manufactured by the Photonics Lightwave Circuit (PLC) technology, and may be hybrid-integrated with the laser diode 100 on the semiconductor substrate 101.

An optical signal output from the laser diode 100 around the resonator 200 may be returned and radiated in a single direction.

The resonator 200 may include a second semiconductor part disposed on the semiconductor substrate 101. The second semiconductor part may include a second lower clad layer 110b, a second active layer 120b, and a second upper clad layer 130b.

The second lower clad layer 110b may include the same material as that of the first lower clad layer 110a. The second upper clad layer 130b may include the same material as that of the first upper clad layer 130a. The second lower clad layer 110b and the second upper clad layer 130b may be used for substantially limiting/restricting light within the resonator 200.

In the exemplary embodiment of the present disclosure, the first lower clad layer 110a and the second lower clad layer 110b may include an n-type doped indium phosphide (InP), and the first upper clad layer 130a and the second upper clad layer 130b may include a p-type doped indium phosphide (InP).

The second active layer 120b may be disposed between the second lower clad layer 110b and the second upper clad layer 130b. The second active layer 120b may include an indium-phosphorous-based semiconductor layer, for example, indium-gallium-arsenic-phosphorous (InGaAsP) based quantum wells.

The resonator 200 may further include a second upper electrode 150b and a second lower electrode 160b which face each other with the second semiconductor part interposed therebetween.

The second lower electrode 160b is disposed on a lower surface of the semiconductor substrate 101, and may include the same material as that of the first lower electrode 160a.

The second upper electrode 150b may be disposed on the second upper clad layer 130b with a second ohmic layer 140b interposed therebetween. The second upper electrode 150b may include the same material as that of the first upper electrode 150a.

In the exemplary embodiment of the present disclosure, the laser diode 100 and the resonator 200 may configure a structure, which is connected by an optical coupling on the single semiconductor substrate 101, and the optical coupling may be a result of the close disposition of the laser diode 100 and the resonator 200 enough to allow the evanescent coupling of an optical signal. As a result, the optical signal transmitted through the laser diode 100 is radiated in a single direction, and is emitted as a mode-locked optical signal having a fine line width to be finally output from the laser diode 100. That is, the laser diode 100 and the resonator 200 are integrated on the single semiconductor substrate 101, so that a cavity of a self-locked optical signal having a fine line width may be caused through the optical coupling of the laser diode 100 and the resonator 200. Here, the cavity may refer to a structure, which maintains an optical signal having a specific resonant wavelength or a wavelength range and suppresses or decreases another optical signal by a destructive interference.

As described above, in the laser system 1000 according to the exemplary embodiment of the present disclosure, it is possible to secure a mode-locked optical signal having a fine line width through the optical coupling of the laser diode 100 and the resonator 200 by forming the laser diode 100 and the resonator 200 on the single semiconductor substrate 101. Since the laser diode 100 includes the first semiconductor part, so that the wave guide layer is formed as a semiconductor device, thereby further securing an optical signal having a fine line width. Accordingly, the laser system 1000 according to the exemplary embodiment of the present disclosure may be applied to an application field, such as a high-rate data optical communication system, in which an optical signal having a fine line width is required.

Further, the laser diode 100 and the resonator 200 are formed on the single substrate 101, so that it is possible to easily manufacture and implement the laser system 1000.

In the meantime, although not illustrated in the drawing, in the laser system 1000, a lens may be disposed between the laser diode 100 and the resonator 200 for the efficient optical coupling of the laser diode 100 and the resonator 200.

In the laser system 1000 according to the exemplary embodiment of the present disclosure, the laser diode 100 and the resonator 200 are formed on the single semiconductor substrate 101, but the present disclosure is not limited thereto. For example, the laser diode 100 and the resonator 200 may be formed on separate substrates, respectively. Even in this case, a lens may be disposed between the laser diode 100 and the resonator 200, and the optical signal generated in the laser diode 100 may be collected through the lens.

FIGS. 3 to 14 are cross-sectional views sequentially illustrating a method of manufacturing the laser system of FIG. 2.

Referring to FIG. 3, the semiconductor substrate 101 is provided. The semiconductor substrate 101 may be a III-V semiconductor substrate. For example, the semiconductor substrate 101 may be an n-type gallium arsenide (GaAs) substrate, or an n-type indium phosphide (InP) substrate. This is a simple example, and the semiconductor substrate 101 may include other various materials. In this case, the semiconductor substrate 101 may be divided into a first region (A in FIG. 1) and a second region (B in FIG. 1).

Referring to FIG. 4, a first semiconductor layer 110′, a second semiconductor layer 120′, a third semiconductor layer 130′, and a fourth semiconductor layer 140′ are sequentially formed on the semiconductor substrate 101.

The first semiconductor layer 110′ may include an n-type doped indium phosphide (InP), but is not limited thereto. The second semiconductor layer 120′ may include an indium-gallium-arsenic-phosphorous (InGaAsP) based quantum well, but is not limited thereto. The third semiconductor layer 130′ may include a p-type doped indium phosphide (InP), but is not limited thereto. The fourth semiconductor layer 140′ may include a p-type indium-gallium-arsenic (InGaAs) layer, but is not limited thereto.

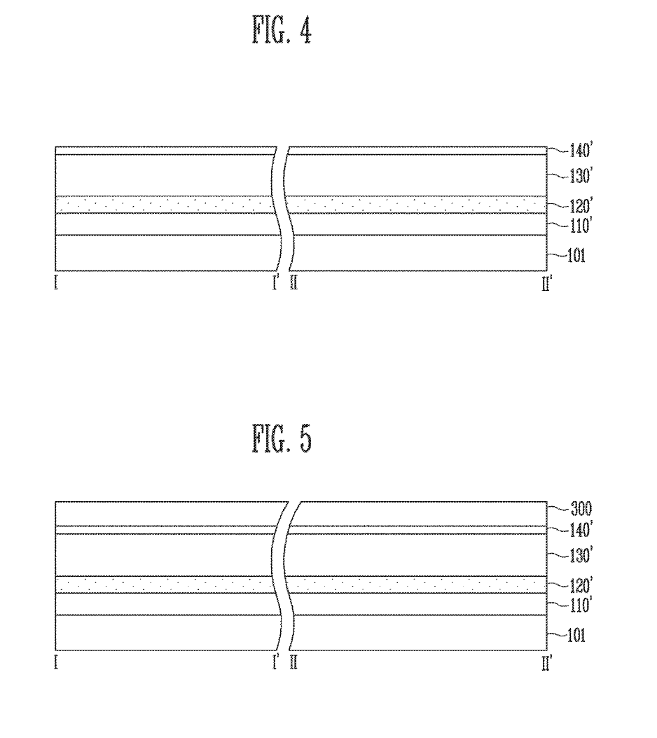

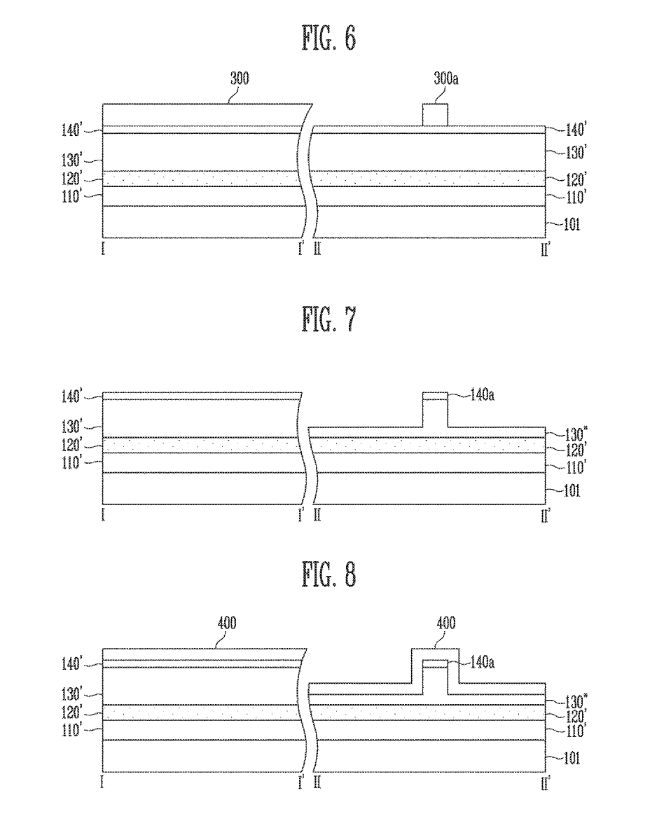

Referring to FIG. 5, a first mask layer 300 is formed on the fourth semiconductor layer 140′. The first mask layer 300 may be an insulating material including a silicon oxide (SiO₂). Then, a first mask pattern 300a is formed on the fourth semiconductor layer 140′ by performing a photo process as illustrated in FIG. 6. The first mask pattern 300a may be formed only in the first region A of the semiconductor substrate 101, in which the laser diode 100 (see FIG. 2) is disposed. The first mask layer 300 disposed in the second region B of the laser diode 100 may be left on the fourth semiconductor layer 140′.

Referring to FIG. 7, an etching process is performed on the fourth semiconductor layer 140′ by using the first mask pattern 300a (see FIG. 6), which is disposed in the first region A of the semiconductor substrate 101, and the first mask layer 300 (see FIG. 6), which is disposed in the second region B of the semiconductor substrate 101. Accordingly, a first ohmic layer 140a is formed on the first region A of the semiconductor substrate 101. In this case, the third semiconductor layer 130′ (see FIG. 6) disposed in the first region A of the semiconductor substrate 101 is formed as a third semiconductor pattern 130″, which is formed in a manner that a remaining region, except for a region of the third semiconductor layer 130′ overlapping the first ohmic layer 140a, is partially etched. After the third semiconductor pattern 130″ and the first ohmic layer 140a are formed, the first mask pattern 300a (see FIG. 6) and the first mask layer 300 (see FIG. 6) are removed.

The etching process may be performed with a dry etching method, such as reactive ion etching (RIE), Magnetically Enhanced Reactive Ion Etching (MERIE), or Inductive Coupled Plasma (ICP), or a wet etching method. In this case, CF₄, CHF₃ and mixed gas of CF₂ and O₂, may be used in the process performed with the dry etching method.

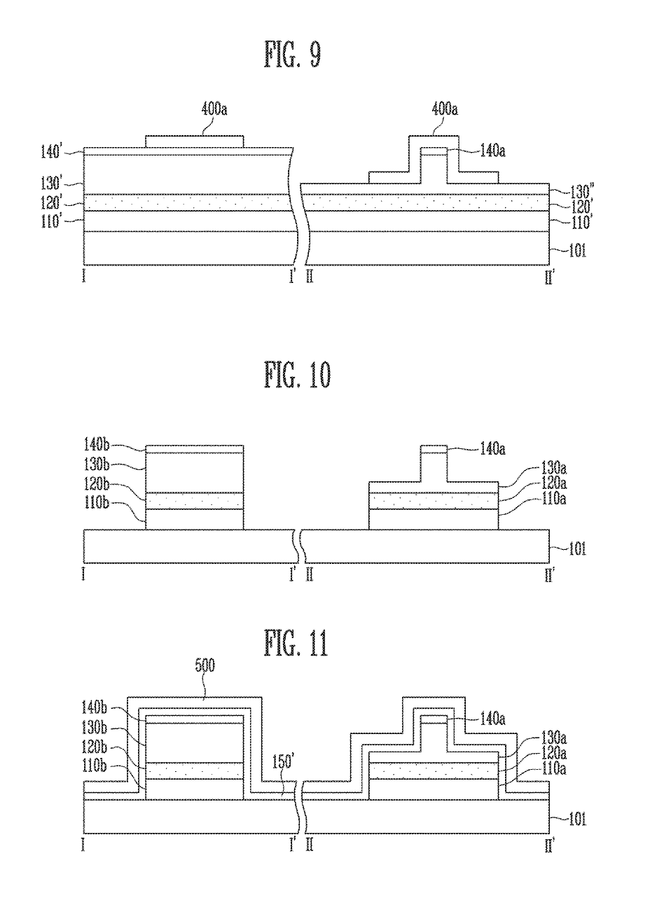

Referring to FIG. 8, a second mask layer 400 is formed on a front surface of the semiconductor substrate 101 including the first ohmic layer 140a. The second mask layer 400 may be an insulating material including a silicon oxide (SiO₂). Then, as illustrated in FIG. 9, a second mask pattern 400a is formed by performing a photo process. The second mask pattern 400a exposes a part of the fourth semiconductor layer 140′ to the outside in the second region B of the semiconductor substrate 101. Further, the second mask pattern 400a completely surrounds the first ohmic layer 140a in the first region A of the semiconductor substrate 101, and exposes a part of the third semiconductor pattern 130″ to the outside.

An etching process is performed on lower structures, which do not overlap the second mask pattern 400a and are exposed to the outside, by using the second mask pattern 400a as an etching mask. Accordingly, as illustrated in FIG. 10, a first semiconductor part is formed in the first region A of the semiconductor substrate 101, and a second semiconductor part is formed in the second region B of the semiconductor substrate 101.

The first semiconductor part includes a first lower clad layer 110a, a first active layer 120a, a first upper clad layer 130a, and a first ohmic layer 140a, which are sequentially stacked on the first region A of the semiconductor substrate 101. The second semiconductor part includes a second lower clad layer 110b, a second active layer 120b, a second upper clad layer 130b, and a second ohmic layer 140b, which are sequentially stacked on the second region B of the semiconductor substrate 101.

Here, the first lower clad layer 110a and the second lower clad layer 110b are formed by patterning the first semiconductor layer 110′ (see FIG. 9) by an etching process. The first active layer 120a and the second active layer 120b are formed by patterning the second semiconductor layer 120′ (see FIG. 9) by the etching process. The first upper clad layer 130a and the second upper clad layer 130b are formed by patterning the third semiconductor layer 130′ (see FIG. 9) and the third semiconductor pattern 130″ (see FIG. 10) by the etching process, respectively. The second ohmic layer 140b is formed by patterning the fourth semiconductor layer 140′ (see FIG. 10) in the second region B of the semiconductor substrate 101 by the etching process.

After the etching process, the second mask pattern 400a (see FIG. 9) is removed. In this case, the etching process may be performed with a dry etching method, such as reactive ion etching (RIE), Magnetically Enhanced Reactive Ion Etching (MERIE), or Inductive Coupled Plasma (ICP).

Referring to FIG. 11, a first metal layer 150′ is formed on the front surface of the semiconductor substrate 101, on which the first semiconductor part and the second semiconductor part are formed. Further, a third mask layer 500 is formed on the first metal layer 150′.

The first metal layer 150′ includes a p-type electrode and is not particularly limited, and may include a material which may make a preferable ohmic-contact with a nitride semiconductor. For example, the first metal layer 150′ may include Ni, Co, Fe, Ti, Cu, Rh, Au, Ru, W, Zr, Mo, Ta, Pt, and Ag, an oxide thereof, and a nitride thereof, and may include a single layer, an alloy, or a multi-layer thereof.

The third mask layer 500 may include an insulating material including a silicon oxide (SiO₂).

Then, as illustrated in FIG. 12, a third mask pattern 500a is formed by performing a photo process. The third mask pattern 500a exposes a part of the first metal layer 150′ to the outside.

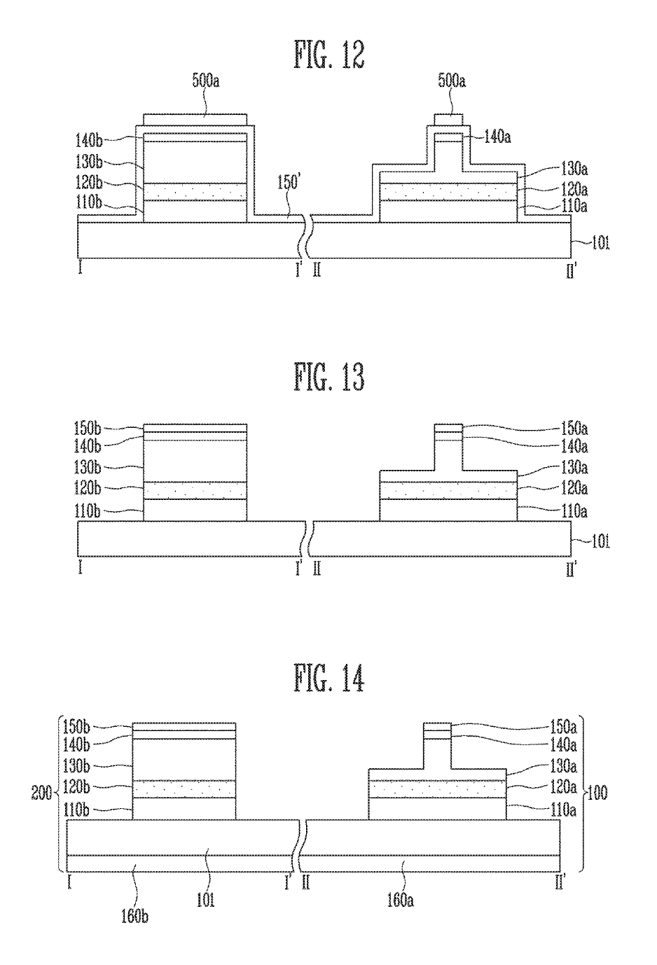

Referring to FIG. 13, an etching process is performed on the first metal layer 150′ (see FIG. 12) by using the third mask pattern 500a as an etching mask. Accordingly, a first upper electrode 150a is formed on the first region A of the semiconductor substrate 101, and a second upper electrode 150b is formed on the second region B of the semiconductor substrate 101. After the first upper electrode 150a and the second upper electrode 150b are formed, the third mask pattern 500a (see FIG. 13) is removed.

The first upper electrode 150a and the second upper electrode 150b may also be formed by primarily forming a mask pattern on the semiconductor substrate 101, forming a metal layer on the mask pattern, and performing a lift-off process and a heat-treatment process (Rapid Thermal Annealing (RTA)).

Referring to FIG. 14, a second metal layer (not illustrated) is formed on a rear surface of the semiconductor substrate 101, and then a first lower electrode 160a and a second lower electrode 160b are formed by a heat-treatment process (Rapid Thermal Annealing (RTA)).

The first lower electrode 160a is disposed in the first region A of the semiconductor substrate 101, and the second lower electrode 160b is disposed in the second region B of the semiconductor substrate 101.

The first lower electrode 160a and the second lower electrode 160b include an n-type electrode and are not particularly limited, and may include a material which may make a preferable ohmic-contact with a III-V semiconductor.

It will be appreciated by those skilled in the art that the present disclosure as described above may be implemented into other specific forms without departing from the technical spirit thereof or essential characteristics. Thus, it is to be appreciated that the exemplary embodiments described above are intended to be illustrative in every sense, and not restrictive. The scope of the present disclosure is represented by the claims to be described below rather than the detailed description, and it is to be interpreted that the meaning and scope of the claims and all the changes or modified forms derived from the equivalents thereof come within the scope of the present disclosure.

What is claimed is:

1. A self-locked laser system, comprising:
a semiconductor substrate;
a laser diode including a first semiconductor part disposed on the semiconductor substrate, and which generates an optical signal;
an unidirectional Whispery Gallery Mode (WGM) resonator including a second semiconductor part disposed on the semiconductor substrate; and
a structure emitting an optical self-locked signal by the optical signal of the laser diode, in which the laser diode and the resonator are optically coupled on the semiconductor substrate.

2. The self-locked laser system of claim 1, wherein the laser diode includes an incident surface inclined at a predetermined angle.

3. The self-locked laser system of claim 1, wherein the first semiconductor part includes an n-type doped first lower clad layer, a p-type doped first upper clad layer, and a first active layer disposed between the first lower clad layer and the first upper clad layer.

4. The self-locked laser system of claim 3, wherein the second semiconductor part includes an n-type doped second lower clad layer, a p-type doped second upper clad layer, and a second active layer disposed between the second lower clad layer and the second upper clad layer.

5. The self-locked laser system of claim 4, wherein the first active layer and the second active layer include a III-V compound semiconductor layer.

6. The self-locked laser system of claim 1, wherein the laser diode includes any one selected from a Fabry-Perot (FP) laser diode, a Distributed Feed-Back (DFB) laser diode, and a Distributed Bragg Reflector (DBR) laser diode.

7. The self-locked laser system of claim 1, further comprising:
a lens disposed between the laser diode and the unidirectional WGM resonator and which collects the optical signal generated by the laser diode.

8. The self-locked laser system of claim 1, further comprising:
a lens collecting the optical signal generated by the laser diode between the laser diode and the unidirectional WGM resonator, in which the laser diode and the unidirectional WGM resonator are formed on separate substrates, respectively.

9. The self-locked laser system of claim 1, wherein the unidirectional WGM resonator includes a passive wave guide having any one selected from low-loss materials including silicon, silica, or CaF₂.

10. The self-locked laser system of claim 9, wherein the unidirectional WGM resonator is hybrid-integrated with the laser diode on the semiconductor substrate.
